(19) United States
(12) Patent Application Publication
(10) Pub. No.: US 2026/0311735 A1
(43) Pub. Date: Oct. 8, 2026

(54) CONTROLLING THE OUTPUT OF A PROBABILISTIC-BIT SPINTRONIC DEVICE

(71) Applicants: COMMISSARIAT À L'ENERGIE ATOMIQUE ET AUX ENERGIES ALTERNATIVES, PARIS (FR); Centre national de la recherche scientifique, PARIS (FR); UNIVERSITE GRENOBLE ALPES, SAINT-MARTIN-D'HERES (FR); INSTITUT POLYTECHNIQUE DE GRENOBLE, GRENOBLE (FR)

(72) Inventors: Kamal DANOUCHI, GRENOBLE (FR); Louis HUTIN, GRENOBLE (FR); Guillaume PRENAT, GRENOBLE (FR)

(21) Appl. No.: 19/537,235

(22) Filed: Feb. 11, 2026

(30) Foreign Application Priority Data
Feb. 13, 2025 (FR) FR2501505

(51) Int. Cl. G11C 11/16

(52) U.S. Cl. CPC G11C 11/1675

(57) ABSTRACT

A process for fabricating a spintronic device includes a magnetic tunnel junction; a bias transistor connected in series with the magnetic tunnel junction; a detection circuit having an input connected to a first detection node and an output for generating a detection signal; the detection circuit including at least a first inverter including a first NMOS transistor and a second PMOS transistor each having: a front gate; a back gate formed by an insulating layer buried in a semiconductor substrate; a control circuit configured to apply a non-zero control voltage to the back gate of at least one of the first or second transistor.

### CROSS-REFERENCE TO RELATED APPLICATION

This application claims priority to foreign French patent application No. FR 2501505, filed on Feb. 13, 2025, the disclosure of which is incorporated by reference in its entirety.

### FIELD OF THE INVENTION

The invention relates to a probabilistic-bit (commonly called p-bit) spintronic device based on a stochastic unit consisting of a magnetic tunnel junction. The invention relates more specifically to a particular architecture for detecting the state of the stochastic unit, enabling it to be configured between a fluctuating configuration or a configuration forced to a predetermined logic state.

### BACKGROUND

A probabilistic bit generator is a device that randomly generates a bit word (0 or 1 binary outputs) based on physical or quantum phenomena, thus ensuring a determined level of randomness or entropy. Unlike conventional devices, which produce deterministic results, this type of device produces a 0 or 1 according to a probability able to be adjusted depending on the needs of the application. This type of probabilistic output is essential in fields such as cryptography, probabilistic algorithms and simulations, where the generation of random binary values guarantees the security or representativeness of calculations. This means that, rather than systematically giving a 0 or 1 deterministically, the device generates a bit word for a predetermined duration in which the distribution between 0 bits and 1 bits is able to be controlled or predefined via input parameters. For example, it would be possible to define a probability of 0.7 of obtaining a 1 and 0.3 of obtaining a 0, which would produce a distribution in a bit word in which roughly 70% of the bits are 1s and 30% are 0s. This probabilistic distribution distinguishes the probabilistic bit generator from pseudorandom number generators, because it relies on sources of physical uncertainty (such as quantum or thermal or magnetic noise), producing a true random in terms of bits.

Magnetic tunnel junction-based probabilistic bit generator devices are a promising solution for exploiting fluctuations in magnetic polarization state in such a structure. FIG. 1a illustrates the circuit diagram of a probabilistic bit generator D0 according to the prior art. The probabilistic bit generator D0 comprises a magnetic tunnel junction MTJ, a control transistor T₀ and a comparator COMP. The magnetic tunnel junction MTJ is a magnetoresistive pillar comprising a stack of layers 11, 12, 13. The stack comprises a first ferromagnetic layer 11 in which the direction of the magnetic polarization is set and uniform. The stack furthermore comprises a second ferromagnetic layer 13 in which the direction of the magnetic polarization is variable. The stack furthermore comprises an oxide barrier layer 12 confined between the first and second ferromagnetic layer 11, 13. The barrier layer 12 plays a crucial role in the magnetoresistive tunnelling effect, allowing electrons to pass through via quantum tunnelling. The first ferromagnetic layer 11 serves as a reference for detecting changes in magnetization in the free ferromagnetic layer 13. The operating principle of the magnetoresistive pillar MTJ is based on the change in electrical resistance as a function of the orientation of the magnetic polarization of the free ferromagnetic layer 13 with respect to the orientation of the magnetic polarization in the reference ferromagnetic layer 11. When the magnetizations of the free and reference layers 11, 13 are parallel, the electrical resistance is low, and reference is made to a low resistive state P. When the magnetizations are antiparallel, the electrical resistance is high, and reference is made to a high resistive state AP. The dimensioning of the magnetic tunnel junction MTJ is such that the magnetic moments of the layers fluctuate between various orientations under the influence of thermal fluctuations, even in the absence of an external magnetic field. These fluctuations are great enough, in relation to the energy barrier separating the two resistive states, for the magnetization no longer to be stable in a fixed direction. Reference is made here to operation in “fluctuation regime” or a “superparamagnetic” state, unlike magnetoresistive memories in which the magnetic layers retain their orientation following programming. Indeed, in a magnetoresistive memory, the energy barrier between the two resistive states is out of range of thermal energy with an amplitude greater than 40xk_{b}T, where k_{b} is the Boltzmann constant and T is the operating temperature of the memory. The operation of the superparamagnetic tunnel junction MTJ is illustrated by the energy diagram in FIG. 1b, which illustrates a first resistive state P and a second resistive state AP separated by an energy barrier ∆E less than or equal to ten times the thermal energy k_{b}T, where k_{b} is the Boltzmann constant and T is the operating temperature of the generator D0. The respective probability of the magnetic tunnel junction MTJ generating 0 bits (high resistive state or vice versa, depending on the convention chosen) and 1 bits (low resistive state or vice versa, depending on the convention chosen) depends on the intensity of the bias current Ic passing through it. The intensity of the current Ic is regulated by the control transistor T₀ connected in series with the magnetic tunnel junction MTJ between a supply node supplying the supply voltage VDD and electrical ground GND. The common node between the magnetic tunnel junction MTJ and the control transistor T₀ forms a first detection node NC1. The comparator COMP is configured to compare the voltage drop across the magnetic tunnel junction, corresponding to the electrical potential V_{DIV} of the first detection node NC1, with a reference voltage V_{REF}, in order to continuously determine the random resistive state of said magnetic tunnel junction.

The bias current Ic is controlled by the input voltage Vᵢₙ applied to the gate of the control transistor T₀. The input voltage Vᵢₙ is advantageously chosen so as to operate in linear regime or in ohmic regime. Increasing the input voltage Vᵢₙ causes the bias current Ic to increase. Increasing the bias current Ic makes the probability P(1) of having a high resistive state AP (conventionally and non-limitingly equivalent to a “1” bit) increase. Conversely, decreasing the bias current Ic makes the probability P(0) of having a low resistive state P (conventionally and non-limitingly equivalent to a “0” bit) increase.

Stochastic computers have an important application in probabilistic bit generators. A stochastic computer based on an array of p-bits is an innovative computational architecture that comprises a plurality of probabilistic bit (p-bit) generators that are interconnected so as to form an array. The p-bit generated by each generator influences the p-bits of the other generators via connection weights, in a manner similar to neural networks or physical models such as the Ising model. This approach makes it possible to simulate complex physical systems, to solve combinatorial problems and to perform approximate logical computations, often with high energy efficiency.

To carry out specific computing operations, it is necessary to set (or force) the output of certain p-bits to 1 or 0. This operation is called “clamping” the output of the p-bit generator. For example, to implement a logic AND operation between two p-bits A and B, it is possible to add a third p-bit C the state of which is influenced by the first two. By forcing A and B to predetermined logic states (no fluctuation here), p-bit C may be configured to oscillate only according to the rules of the logic operation C=(A) AND (B). The interaction between these p-bits is governed by synaptic weights and bias terms. The updating of C is determined by a sigmoid function that depends on the weighted sum of the inputs A and B. This operation of setting certain p-bits allows the array to carry out computations with fixed variables in a stochastic framework. More particularly, the clamping operation makes it possible to solve various sub-problems, representing special cases of the configuration in which all p-bits are free, based on the same physical array. For example, with a multiplier circuit function, it is possible to set the bits of the factors to carry out a multiplication, or to set the bits of the product to carry out a factorization, or to set any bits to solve any Boolean satisfiability problem.

In this context, a major technical problem is encountered, namely that of implementing the clamping operation in an array consisting of several hundred probabilistic bit generators without drastically increasing the size of the stochastic computer or its energy consumption.

One known solution in this context consists in adding, for each probabilistic bit generator, a first pull-up transistor that connects its output to the supply voltage when activated and a second pull-down transistor that connects its output to electrical ground when activated. The drawback of this solution is a considerable increase in the size of a stochastic computer implementing a plurality of probabilistic bit generators. The addition of a pair of transistors for each probabilistic bit generator also increases leakage currents in the stochastic computer, thereby causing an increase in its energy consumption.

### SUMMARY OF THE INVENTION

To overcome the limitations of existing solutions, the invention proposes a spintronic device configured to produce an output that is forced to a predefined logic state in a first configuration, or to generate random or pseudorandom bits with a controlled distribution in a second configuration. It differs from conventional generators through a detection architecture based on controlling the switching threshold of at least one inverter in the detection chain. The inverter is realized by SOI transistors, more advantageously FDSOI transistors. Control is achieved by applying a control voltage to the back gates of the transistors that form said inverter. This solution thus makes it easier to carry out computations involving stochastic generators in an array of several hundred probabilistic generators, while at the same time maintaining a compact size and low energy consumption for the stochastic computer.

The invention relates to a spintronic device comprising:

a magnetic tunnel junction having a resistance that fluctuates between at least two distinct resistive states depending on its magnetization;

a bias transistor connected in series with the magnetic tunnel junction; the common node between the bias transistor and the magnetic tunnel junction constituting a first detection node;

a detection circuit having an input connected to the first detection node and an output for generating a detection signal; the detection circuit comprising at least a first inverter comprising a first NMOS transistor and a second PMOS transistor that are connected in series between electrical ground and a supply node supplying a supply voltage, and each having:

a front gate;

a back gate formed by an insulating layer buried in a semiconductor substrate;

the front gates of the first and second transistor receiving the potential of the first detection node or an intermediate signal generated from the potential of the first detection node;

a control circuit configured, in a first configuration, to apply a non-zero control voltage to the back gate of at least one of the first or second transistor in order to set the detection signal to electrical ground or to the voltage of the supply node, depending on the sign of the control voltage.

According to one particular aspect of the invention, the control circuit is furthermore configured, in a second configuration, to apply a zero control voltage to the back gate of at least one of the first or second transistor such that the detection signal varies with fluctuations in the resistance of the magnetic tunnel junction.

According to one particular aspect of the invention, the first transistor and the second transistor are fully depleted silicon on insulator transistors.

According to one particular aspect of the invention, the control circuit is configured to apply the control voltage simultaneously to the back gates of the first transistor and second transistor.

According to one particular aspect of the invention, the detection circuit comprises a chain of a plurality of inverters; said chain comprising the first inverter.

According to one particular aspect of the invention, the detection circuit comprises a comparator having a first input connected to the first detection node and a second input intended to receive a reference voltage and an output node connected to the front gates of the first and second transistor.

According to one particular aspect of the invention, the first detection node is connected to the front gates of the first and second transistor.

According to one particular aspect of the invention, the device furthermore comprises a computer circuit configured to generate a probabilistic bit from the detection signal based on sampling or averaging by determining the proportion of each resistive state of the magnetic tunnel junction during a predetermined period.

According to one particular aspect of the invention, the magnetic tunnel junction is a superparamagnetic tunnel junction.

According to one particular aspect of the invention, the magnetic tunnel junction is arranged on a write track made of a spin Hall effect material or an orbital Hall effect material.

According to one particular aspect of the invention, the magnetic tunnel junction comprises:

a first reference ferromagnetic layer in which the direction of the magnetic polarization is set;

a second ferromagnetic layer in which the direction of the magnetic polarization is variable;

an oxide tunnel barrier layer confined between the first and second ferromagnetic layer.

According to one particular aspect of the invention, the thickness of the second layer is less than 100 nm.

According to one particular aspect of the invention, the diameter of the magnetic tunnel junction is less than 10 nm.

The invention also relates to a stochastic computer comprising an array of a plurality of interconnected probabilistic bit generators, the array comprising at least one probabilistic bit generator realized by the spintronic device according to the invention.

### BRIEF DESCRIPTION OF THE DRAWINGS

Further features and advantages of the present invention will become more clearly apparent upon reading the following description, with reference to the following appended drawings.

FIG. 1a illustrates a probabilistic bit generator D0 according to the prior art. This figure has already been described.

FIG. 1b illustrates an energy diagram of the probabilistic bit generator D0 according to the prior art. This figure has already been described.

FIG. 2a illustrates a probabilistic bit generator D1 according to a first embodiment of the invention.

FIG. 2b illustrates cross-sectional views of the implementation of four different FDSOI transistors.

FIG. 2c illustrates the variation of the detection signal of the probabilistic bit generator according to a first embodiment of the invention in response to a variation of the control voltage.

FIG. 3 illustrates a probabilistic bit generator D1 according to a second embodiment of the invention.

FIG. 4 illustrates a probabilistic bit generator D1 according to a third embodiment of the invention.

FIG. 5 illustrates a probabilistic bit generator D1 according to a fourth embodiment of the invention.

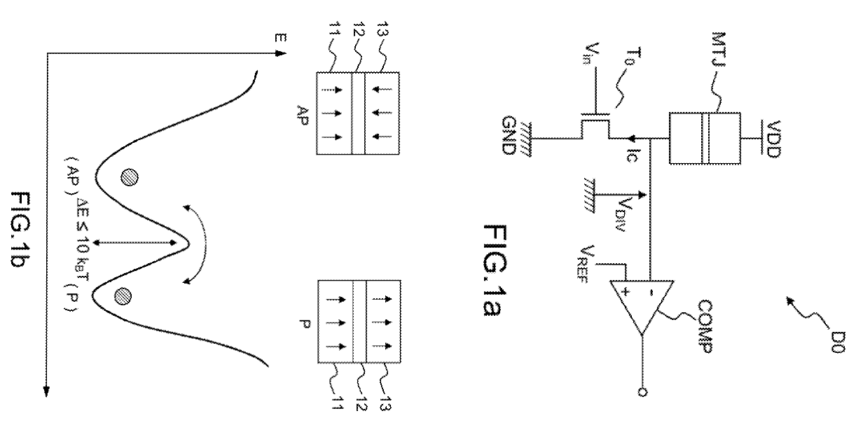

### DETAILED DESCRIPTION

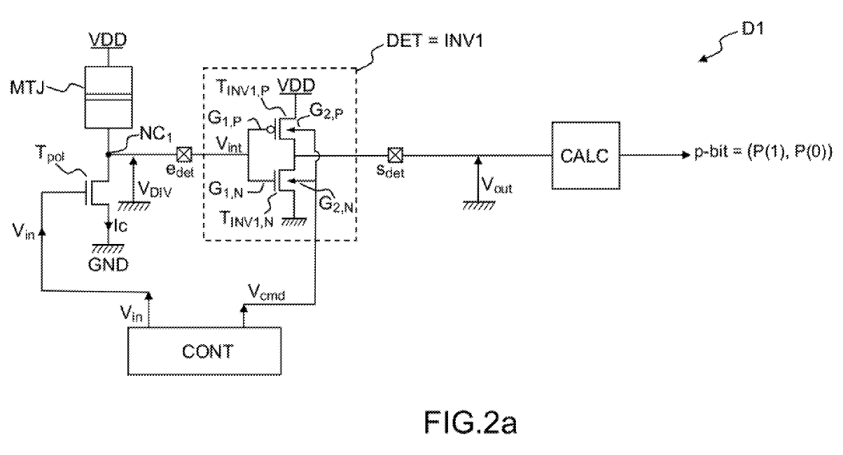

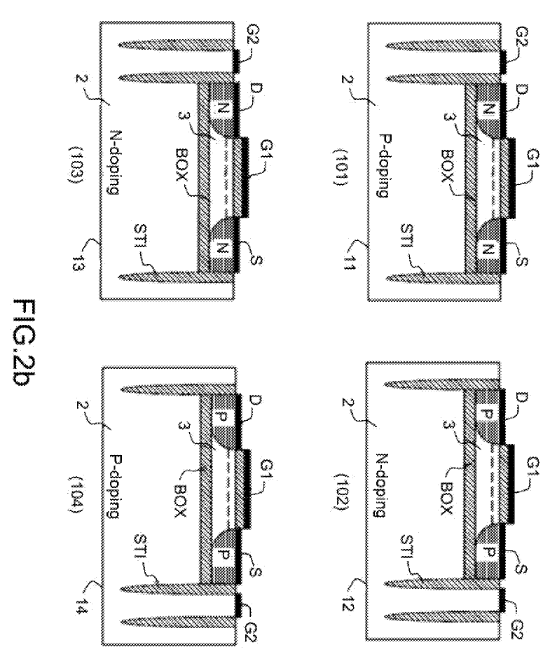

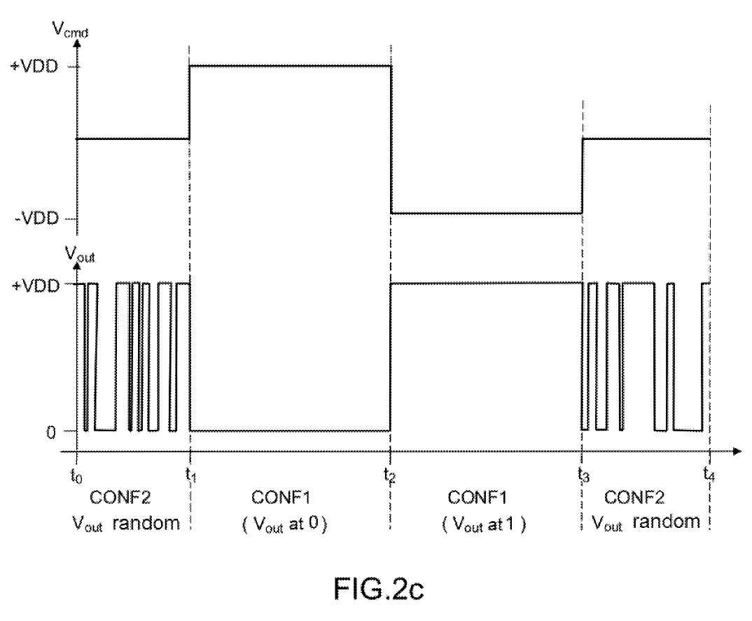

FIG. 2a illustrates a spintronic device, and more particularly a probabilistic bit generator D1 according to a first embodiment of the invention. The probabilistic bit p-bit generator D1 comprises a magnetic tunnel junction MTJ, a bias transistor Tₚₒₗ, a detection circuit DET, a computer circuit CALC and a control circuit CONT. The magnetic tunnel junction MTJ is dimensioned so as to operate in fluctuation regime in response to thermal agitation. The magnetic tunnel junction MTJ is formed by a stack of layers. The stack comprises a first reference ferromagnetic layer 11 in which the direction of the magnetic polarization is set and uniform. The stack furthermore comprises a second ferromagnetic layer 13 in which the direction of the magnetic polarization is variable. The stack furthermore comprises an oxide barrier layer 12 confined between the first and second ferromagnetic layer 11, 13. The diameter (or diagonal, depending on the shape) of the magnetic tunnel junction MTJ is less than 100 nm. More advantageously, the thickness of the second layer 13 is less than 10 nm, preferably less than 5 nm. This makes it possible to lower the energy barrier separating the first resistive state P and the second resistive state AP to a value less than or equal to ten times the thermal energy k_{B}T, and therefore to produce a superparamagnetic tunnel junction MTJ. It will be recalled that a superparamagnetic tunnel junction has a fluctuating resistive state in which magnetization is unstable under thermal influence.

By way of non-limiting illustration, the bias transistor Tₚₒₗ is an NMOS field-effect transistor. The bias transistor Tₚₒₗ operates like a modulable current source configured to inject a control current Ic through the magnetic tunnel junction MTJ so as to control the distribution between the two resistive states of the superparamagnetic tunnel junction MTJ. The bias transistor Tₚₒₗ is connected in series with the magnetic tunnel junction MTJ between a supply node supplying the supply voltage VDD and electrical ground GND. Increasing the bias current Ic makes the probability P(1) of having a high resistive state AP (equivalent to a “1” bit) increase. Conversely, decreasing the bias current Ic makes the probability P(0) of having a low resistive state P (equivalent to a “0” bit) increase. The bias current Ic is controlled by applying an input voltage Vᵢₙ to the gate of the bias transistor Tₚₒₗ.The control circuit CONT is configured to apply the variable input voltage Vᵢₙ to the gate of the bias transistor Tₚₒₗ. The range of variation of the input voltage Vᵢₙ is chosen such that the bias transistor Tₚₒₗ operates in ohmic regime so as to ensure linear behaviour of the generator.

The common node between the bias transistor Tₚₒₗ and the magnetic tunnel junction MTJ forms a first detection node NC1. The potential V_{DIV} of the first detection node NC1 varies in square waves in accordance with the voltage drop across the magnetic tunnel junction MTJ, which depends on the resistance value of said junction. When the magnetic tunnel junction MTJ is in a high resistive state AP, the voltage V_{DIV} is at a low voltage, and when the magnetic tunnel junction MTJ is in a low resistive state P, the voltage V_{DIV} is at a high voltage.

The detection circuit DET comprises a first inverter INV1 formed by a first NMOS transistor T_{INV1,N} and a second PMOS transistor T_{INV1,P} connected in series between ground and the supply node supplying VDD. In the example illustrated, the detection circuit DET is formed by the inverter INV1. The input e_{det} corresponds to the input of the inverter INV1 and the output s_{det} corresponds to the output of the inverter INV1. The first and second transistor T_{INV1,N}, T_{INV1,P} are each produced on an insulating layer buried in the silicon on insulator (SOI) substrate, and more advantageously on a fully depleted silicon on insulator (FDSOI) substrate. To better understand the invention, FIG. 2b illustrates cross-sectional views of the implementation of four different FDSOI transistors. Diagram 101 is an NMOS regular voltage threshold (RVT) transistor 11. Diagram 102 is a PMOS regular voltage threshold (PMOS-RVT) FDSOI transistor 12. Diagram 103 is an NMOS low voltage threshold (LVT) FDSOI transistor 13. Diagram 104 is a PMOS low voltage threshold (PMOS-LVT) FDSOI transistor 14. The NMOS-RVT transistor 11 in diagram 101 employing FDSOI technology is produced on a P-doped semiconductor-based substrate 2. A layer of insulating dielectric material, generally an oxide denoted BOX, separates the assembly made up of the N-doped zones forming the drain D and the source S and the semiconductor region 3 containing the conduction channel from the rest of the substrate 2. A control gate G1 is obtained by stacking an oxide layer and a metal layer on the region 3 of the conduction channel, in a manner similar to a gate of a MOS transistor on a solid semiconductor substrate. Shallow trench isolations STI made of oxide are added to each side of the transistor 11 to electrically insulate the component. Layers of conductive material, generally made of metal, are deposited on the gate G1, the drain D and the source S to enable electrical connection to these terminals. In addition, an additional terminal G2 is added by depositing a metal layer on the region delimited by two shallow trench isolations STI adjacent to the transistor 11. Applying a voltage to the terminal G2 makes it possible to bias the buried oxide layer BOX, which acts as a back gate. This thus makes it possible to vary the threshold voltage Vₜₕ of the transistor 1. This operation is commonly referred to as back-biasing. The PMOS-RVT transistor 12 in diagram 102 has exactly the same structure as the one in diagram 101, except for the distribution of the doping, since it is a PMOS transistor. The substrate 2 is N-doped, and the drain D and the source S are P-doped. With regard to the NMOS-LVT transistor 13, the only difference from the transistor 11 in diagram 101 is the inversion of the doping type of the N-doped substrate 2. With regard to the PMOS-LVT transistor 14, the only difference from the transistor 12 in diagram 102 is the inversion of the doping type of the P-doped substrate 2. Generally speaking, the invention may be implemented with SOI transistors or with any transistor having an insulating layer buried in the substrate the conductance of which is able to be controlled via a back gate connected to the buried insulating layer.

In the probabilistic bit generator D1 according to the invention, the first transistor T_{INV1,N} thus comprises a front gate G_{1,N} and a back gate G_{2,N} and the second transistor T_{INV1,P} comprises a front gate G_{1,P} and a back gate G_{2,P}.The two front gates G_{1,N} and G_{1,P} are interconnected and directly receive the signal V_{DIV} corresponding to the potential of the first detection node NC1. The back gates G_{2,N}, G_{2,P} of the transistors of the inverter INV1 receive a control voltage V_{cmd} generated by the control circuit CONT. The detection circuit DET is able to be configured in a first configuration CONF1 and a second configuration CONF2. When the first configuration CONF1 is chosen, the output s_{det} of the detection circuit DET is forced to a voltage chosen from the supply voltage VDD or to electrical ground. The first configuration CONF1 corresponds to an operation of clamping the probabilistic bit generator in a logic state chosen from 1 or 0. The clamping operation gives a deterministic and non-probabilistic value with a probability of “1” or “0” equal to 100%. When the first configuration CONF1 is chosen, the detection circuit DET is configured to generate a set detection signal Vₒᵤₜ independently of random variations of the resistive state of the magnetic tunnel junction MTJ. The second configuration CONF2 corresponds to operation of the probabilistic bit generator in which the detection circuit DET is configured to generate a detection signal Vₒᵤₜ that varies depending on the resistive state of the magnetic tunnel junction MTJ from the potential V_{DIV} of the first detection node NC1.

When the first configuration CONF1 is chosen, the control circuit CONT is configured to apply a non-zero control voltage V_{cmd} to the back gate of the first and second transistor T_{INV1,N}, T_{INV1,P} so as to set the detection signal Vₒᵤₜ at the output of the detection circuit DET to electrical ground GND or to the voltage of the supply node VDD. When the control voltage V_{cmd} is negative, the threshold voltage V_{th,N} of the first transistor T_{INV1,N} increases and the threshold voltage V_{th,P} of the second transistor T_{INV1,P} increases. The increase in the threshold voltages V_{th,N} and V_{th,P} induces a decrease in the switching threshold of the first inverter INV1. The decrease in the switching threshold of the first inverter INV1 causes the output of the inverter INV1 to be set to the voltage of the supply node VDD when the amplitude of this decrease is sufficient. It is thus possible to set the detection signal Vₒᵤₜ to a high logic state by applying a negative control voltage V_{cmd} to the back gates G_{2,N}, G_{2,P} of the transistors T_{INV1,N}, T_{INV1,P}. Conversely, when the control voltage V_{cmd} is positive, the threshold voltage V_{th,N} of the first transistor T_{INV1,N} decreases and the threshold voltage V_{th,P} of the second transistor T_{INV1,P} decreases. The reduction in the threshold voltages V_{th,N} and V_{th,P} induces an increase in the switching threshold of the first inverter INV1. The increase in the switching threshold of the first inverter INV1 causes the output of the inverter INV1 to be set to electrical ground when the amplitude of this decrease is sufficient. It is thus possible to set the detection signal Vₒᵤₜ of the detection circuit DET to a low logic state by applying a positive control voltage V_{cmd} to the back gates G_{2,N}, G_{2,P} of the transistors T_{INV1,N}, T_{INV1,P}.

As an alternative, the control voltage V_{cmd} is applied only to the back gate G_{2,N} of the first transistor T_{INV1,N}.When the control voltage V_{cmd} is positive, the detection signal Vₒᵤₜ is forced to electrical ground (clamping in logic state “0”). When the control voltage V_{cmd} is negative, the detection signal Vₒᵤₜ is forced to the supply voltage VDD (clamping in logic state “1”).

As an alternative, the control voltage V_{cmd} is applied only to the back gate G_{2,P} of the second transistor T_{INV1,P}.When the control voltage V_{cmd} is positive, the detection signal Vₒᵤₜ is forced to electrical ground (clamping in logic state “0”). When the control voltage V_{cmd} is negative, the detection signal Vₒᵤₜ is forced to the supply voltage VDD (clamping in logic state “1”).

More generally, the probabilistic bit generator D1 according to the invention makes it possible to force its output to a predetermined logic state with a probability of 100%, without adding additional components or increasing the size of the circuit. The clamping operation is carried out by controlling the switching threshold of the first inverter INV1 by applying the non-zero control voltage V_{cmd} to the back gate of at least one transistor of said inverter INV1. It is advantageous to use FDSOI transistors to implement the inverter INV1, because this enables more precise control of the switching threshold of the inverter, and thus of the output of the generator D1. The simultaneous application of the control voltage V_{cmd} to the two transistors T_{INV1,N}, T_{INV1,P} makes it possible to ensure that the switching threshold of the inverter INV1 drifts towards the supply voltage VDD or electrical ground GND, and thus avoid the risk of unwanted fluctuations during a clamping operation.

When the second configuration CONF2 is chosen, the control voltage V_{cmd} is zero and the inverter INV1 operates with a switching threshold between the maximum value of the potential V_{DIV,max} of the first detection node NC1 and the minimum value of the potential V_{DIV,min} of the first detection node NC1. The detection circuit DET is then configured to generate a detection signal Vₒᵤₜ that reproduces the variations of the potential of the first detection node NC1. The detection circuit thus makes it possible to detect variations of the resistive state of the junction over the entire range of variation of the input signal Vᵢₙ.

The computer circuit CALC is configured to generate a probabilistic bit from the detection signal Vₒᵤₜ by determining the proportion of each resistive state of the magnetic tunnel junction MTJ during a predetermined period. The computer circuit is configured to compute the distribution between bits in a high logic state “1” and bits in a low logic state “0” in a bit sequence corresponding to the detection signal Vₒᵤₜ for a predetermined duration. For example, the computer circuit CALC is configured to sample the detection signal Vₒᵤₜ every 1 ns during a period of 10 µs. The number of bits at “1” (or bits at “0”) is computed during the period of 10 µs, this corresponding to a sample of 10000 logic bits to determine the proportion of bits at “1” and at “0”, this corresponding to the probabilistic bit p-bit = (P(1),P(0)). When the detection signal Vₒᵤₜ is set to VDD, the computer generates a probabilistic bit p-bit = (100%,0%). When the detection signal Vₒᵤₜ is set to 0 V, the computer generates a probabilistic bit p-bit = (0%,100%).

As an alternative, the computer circuit CALC is configured to compute the average of the detection signal s1 over the duration of the period. The average is proportional to the number of bits equal to “1” over the sampled period.

FIG. 2c illustrates the variation of the detection signal Vₒᵤₜ of the probabilistic bit generator according to a first embodiment of the invention in response to a variation of the control voltage V_{cmd}. During the period t0 to t1, the control voltage V_{cmd} is kept at 0 by the control circuit CONT. The generator D1 operates in the second configuration CONF2, corresponding to a regime of random fluctuations observed on the detection signal Vₒᵤₜ. During the period t1 to t2, the control voltage V_{cmd} is kept at +VDD by the control circuit CONT. The generator D1 operates in the first configuration CONF1, corresponding to a detection signal Vₒᵤₜ forced to electrical ground. During the period t2 to t3, the control voltage V_{cmd} is kept at -VDD by the control circuit CONT. The generator D1 operates in the first configuration CONF1, corresponding to a detection signal Vₒᵤₜ forced to VDD. During the period t3 to t4, the control voltage V_{cmd} is kept at 0 by the control circuit CONT. The generator D1 operates in the second configuration CONF2, corresponding to a regime of random fluctuations observed on the detection signal Vₒᵤₜ.

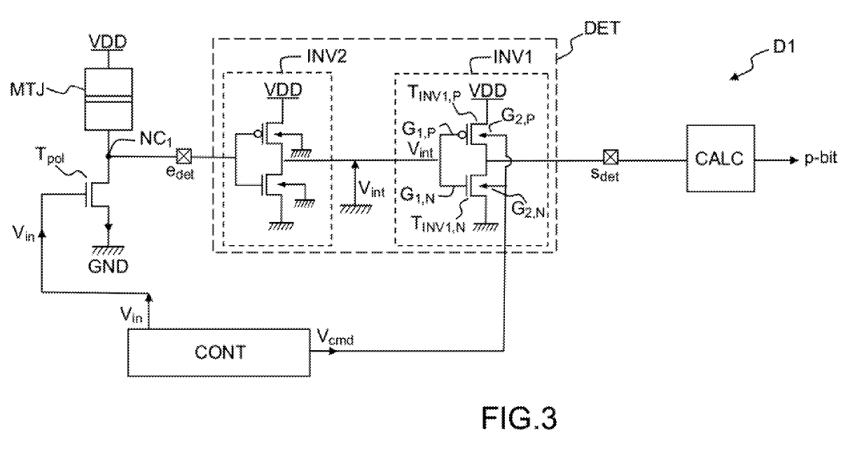

FIG. 3 illustrates a probabilistic bit generator D1 according to a second embodiment of the invention. The second embodiment has the same technical features and advantages described in detail for the first embodiment. The detection circuit DET in the second embodiment furthermore comprises a second inverter INV2 connected upstream of the first inverter INV1. The input of the second inverter INV2 is connected to the first detection node NC1, and its output is connected to the front gates G_{1,N}, G_{1,P} of the transistors T_{INV1,N}, T_{INV1,P} of the first inverter INV1. The second inverter INV2 generates an intermediate voltage Vᵢₙₜ from the potential V_{DIV} of the first detection node NC1. The substrates of the transistors forming the second inverter INV2 are connected to electrical ground in order to obtain a switching threshold enabling the variations of the potential V_{DIV} to be detected. The second inverter INV2 is dimensioned so as to detect small variations of the potential V_{DIV} at its input and amplify them at its output. This advantageously enables more precise detection of fluctuations when the second configuration CONF2 is chosen. Moreover, the second inverter INV2 placed upstream of the first inverter INV1 enables more stable biasing of the transistors T_{INV1,N}, T_{INV1,P} of the first inverter INV1.

According to one particular aspect of the second embodiment, the detection circuit DET comprises a chain formed of N inverters, with N a natural integer greater than 1. The chain of inverters comprises at least the first inverter INV1 realized by transistors T_{INV1,N}, T_{INV1,P} the threshold voltages Vₜₕ of which are controlled by the control voltage V_{cmd} applied to their back gates.

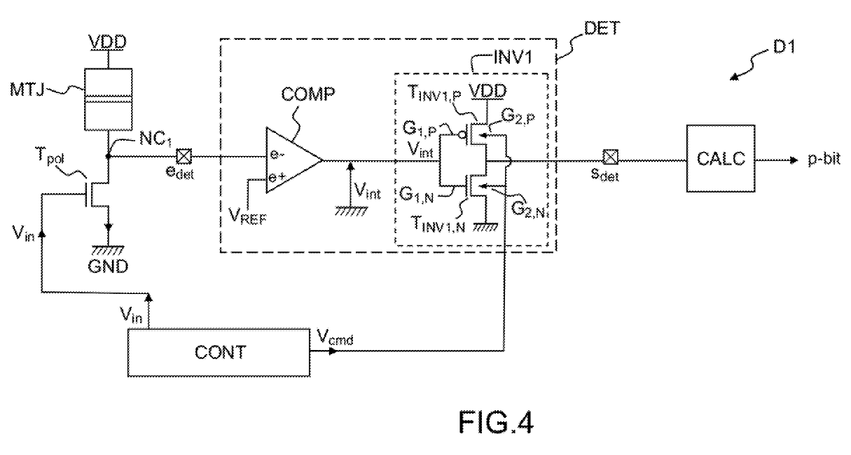

FIG. 4 illustrates a probabilistic bit generator D1 according to a third embodiment of the invention. The third embodiment has the same technical features and advantages described in detail for the first embodiment. The detection circuit DET in the third embodiment furthermore comprises a comparator COMP connected upstream of the first inverter INV1. The comparator COMP comprises a first input e- connected to the detection node NC1; and a second input receiving a reference voltage V_{REF}. In the example illustrated and without limitation, the first input e- is the inverting input of the comparator, and the second input e+ is the non-inverting input. Thus, when the magnetic tunnel junction MTJ is in a high resistive state AP, the voltage received by the first input of the comparator is less than the reference voltage V_{REF}, and the comparator generates an intermediate signal Vᵢₙₜ equal to VDD, equivalent to a bit equal to “1”. When the magnetic tunnel junction MTJ is in a low resistive state P, the voltage received by the first input of the comparator is greater than the reference voltage V_{REF}, and the comparator generates an intermediate signal Vᵢₙₜ equal to 0, equivalent to a bit equal to “0”. The output of the comparator COMP is connected to the front gates G_{1,N}, G_{1,P} of the transistors T_{INV1,N}, T_{INV1,P} of the first inverter INV1. The comparator COMP is dimensioned so as to detect small variations of the potential V_{DIV} at its input and amplify them at its output. This advantageously enables more precise detection of fluctuations when the second configuration CONF2 is chosen. Moreover, when the first configuration CONF1 is chosen, i.e. clamping operation, it is possible to lower or increase the value of the reference voltage V_{REF} so as to set Vᵢₙₜ to a fixed voltage. The combination of the comparator COMP with the controlling of the back gates of the transistors of the first inverter INV1 makes it possible to increase the reliability of the operation of clamping the output of the generator D1 according to the invention.

According to one particular aspect of the third embodiment, the detection circuit DET comprises a chain formed of N inverters, with N a natural integer greater than 1. The chain of inverters comprises at least the comparator COMP and the first inverter INV1 realized by transistors T_{INV1,N}, T_{INV1,P} as has already been described.

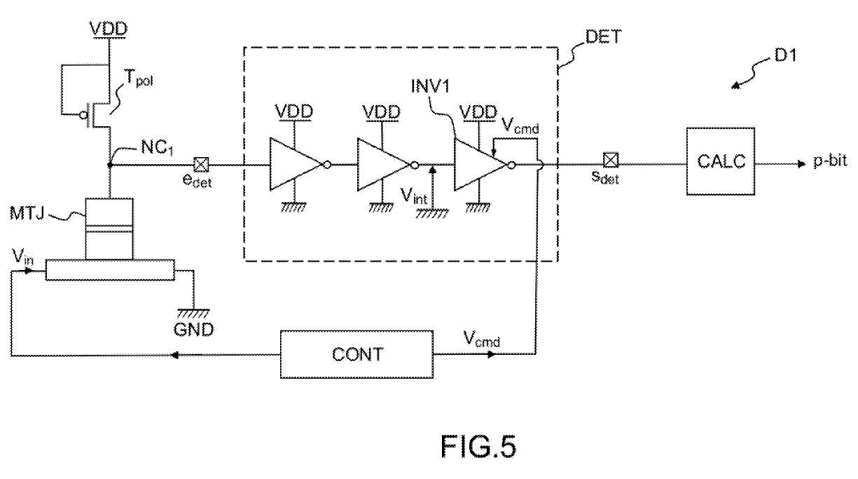

FIG. 5 illustrates a probabilistic bit generator D1 according to a fourth embodiment of the invention. The fourth embodiment has the same technical features and advantages described in detail for the previous embodiments. In the generator D1 according to the fourth embodiment, the magnetic tunnel junction MTJ is arranged on a write track SOT made of a spin Hall effect material or an orbital Hall effect material. The interface between the magnetic tunnel junction MTJ and the write track SOT is on the side of the free ferromagnetic layer. The direction of the stack forming the magnetic tunnel junction MTJ is orthogonal to the plane formed by the layer forming the write track SOT. The write track SOT is made of a spin Hall effect material (also known as a spin-orbit couple effect material), for example beta-phase tungsten or bismuth antimonide or a stack of two layers, one made of tantalum and the other of tungsten, or a BiSbTe alloy. The control means generate a write current Iᵢₙ through the write track SOT in one direction. This induces spin currents that interact with the free ferromagnetic layer. This interaction makes it possible to control the direction of magnetic polarization in the free ferromagnetic layer of the junction MTJ in accordance with the direction of the write current in the write track SOT. Controlling the direction of magnetic polarization in the free ferromagnetic layer makes it possible to modify the electrical resistance R(MTJ) of the magnetic tunnel junction MTJ without injecting a write current into it, thereby considerably increasing the robustness of the spintronic device. The detection circuit DET comprises at least the first inverter INV1, already described, in order to achieve operation in the first configuration CONF1 (forced output with a probability of 100%) or else operation in the second configuration CONF2 (stochastic fluctuation of the output).

The spintronic device described in the invention uses the random properties of a magnetic tunnel junction (MTJ) to generate random or pseudorandom bits with a controlled distribution, or to produce an output set to a predefined logic state. Unlike conventional generators, this device adopts an innovative detection architecture that makes it possible to change configuration without the need for additional components. This approach makes it easier to carry out computations involving stochastic generators in an array of several hundred probabilistic generators, while at the same time limiting the size and energy consumption of the stochastic computer.

1. A spintronic device (D1) comprising:
a magnetic tunnel junction (MTJ) having a resistance that fluctuates between at least two distinct resistive states (P, AP) depending on its magnetization;
a bias transistor (Tₚₒₗ) connected in series with the magnetic tunnel junction (MTJ); the common node between the bias transistor (Tₚₒₗ) and the magnetic tunnel junction (MTJ) constituting a first detection node (NC1);
a detection circuit (DET) having an input (e_{det}) connected to the first detection node (NC1) and an output (s_{det}) for generating a detection signal (Vₒᵤₜ); the detection circuit (DET) comprising at least a first inverter (INV1) comprising a first NMOS transistor (T_{INV1,N}) and a second PMOS transistor (T_{INV1,P}) that are connected in series between electrical ground (GND) and a supply node supplying a supply voltage (VDD), and each having:
a front gate (G_{1,N} G_{1,P});
a back gate (G_{2,N} G_{2,P}) formed by an insulating layer (BOX) buried in a semiconductor substrate;
the front gates (G_{1,N} G_{1,P}) of the first and second transistor (T_{INV1,N} T_{INV1,P}) receiving the potential (V_{DIV}) of the first detection node (NC1) or an intermediate signal (Vᵢₙₜ) generated from the potential (V_{DIV}) of the first detection node (NC1);
a control circuit (CONT) configured, in a first configuration (CONF1), to apply a non-zero control voltage (V_{cmd}) to the back gate (G_{2,N} G_{2,P}) of at least one of the first or second transistor (T_{INV1,N} T_{INV1,P}) in order to set the detection signal (Vₒᵤₜ) to electrical ground (GND) or to the voltage of the supply node (VDD), depending on the sign of the control voltage (V_{cmd}).

2. The spintronic device (D1) according to claim 1, wherein the control circuit (CONT) is furthermore configured, in a second configuration (CONF2), to apply a zero control voltage (V_{cmd}) to the back gate (G_{2,N} G_{2,P}) of at least one of the first or second transistor (T_{INV1,N} T_{INV1,P}) such that the detection signal (Vₒᵤₜ) varies with fluctuations in the resistance of the magnetic tunnel junction.

3. The spintronic device (D1) according to claim 1, wherein the first transistor (T_{INV1,N}) and the second transistor (T_{INV1,P}) are fully depleted silicon on insulator transistors.

4. The spintronic device (D1) according to claim 1, wherein the control circuit (CONT) is configured to apply the control voltage (V_{cmd}) simultaneously to the back gates (G_{2,N} G_{2,P}) of the first transistor (T_{INV1,N}) and second transistor (T_{INV1,P}).

5. The spintronic device (D1) according to claim 1, wherein the detection circuit (DET) comprises a chain of a plurality of inverters (INV1, INV2, INV3); said chain comprising the first inverter (INV1).

6. The spintronic device (D1) according to claim 1, wherein the detection circuit comprises a comparator (COMP) having a first input connected to the first detection node (NC1) and a second input intended to receive a reference voltage (V_{REF}) and an output node connected to the front gates (G_{1,N} G_{1,P}) of the first and second transistor (T_{INV1,N} T_{INV1,P}).

7. The spintronic device (D1) according to claim 1, wherein the first detection node (NC1) is connected to the front gates (G_{1,N} G_{1,P}) of the first and second transistor (T_{INV1,N} T_{INV1,P}).

8. The spintronic device (D1) according to claim 1, furthermore comprising a computer circuit (CALC) configured to generate a probabilistic bit from the detection signal (Vₒᵤₜ) based on sampling or averaging by determining the proportion of each resistive state of the magnetic tunnel junction (MTJ) during a predetermined period.

9. The spintronic device (D1) according to claim 1, wherein the magnetic tunnel junction (MTJ) is a superparamagnetic tunnel junction.

10. The spintronic device (D1) according to claim 1, wherein the magnetic tunnel junction (MTJ) is arranged on a write track (SOT) made of a spin Hall effect material or an orbital Hall effect material.

11. The spintronic device (D1) according to claim 1, wherein the magnetic tunnel junction (MTJ) comprises:
a first reference ferromagnetic layer wherein the direction of the magnetic polarization is set;
a second ferromagnetic layer wherein the direction of the magnetic polarization is variable;
an oxide tunnel barrier layer confined between the first and second ferromagnetic layer.

12. The spintronic device (D1) according to claim 11, wherein the thickness of the second layer is less than 100 nm.

13. The spintronic device (D1) according to claim 11, wherein the diameter of the magnetic tunnel junction (MTJ) is less than 10 nm.

14. A stochastic computer comprising an array of a plurality of interconnected probabilistic bit (p-bit) generators (D1), the array comprising at least one probabilistic bit (p-bit) generator (D1) realized by the spintronic device (D1) according to claim 1.
